(19) United States
(12) Patent Application Publication
(10) Pub. No.: US 2013/0015560 A1
(43) Pub. Date: Jan. 17, 2013

(54) GROWTH OF BULK GROUP-III NITRIDE CRYSTALS AFTER COATING THEM WITH A GROUP-III METAL AND AN ALKALI METAL

(71) Applicants: Siddha Pimputkar, Goleta, CA (US); James S. Speck, Goleta, CA (US)

(72) Inventors: Siddha Pimputkar, Goleta, CA (US); James S. Speck, Goleta, CA (US)

(73) Assignee: THE REGENTS OF THE UNIVERSITY OF CALIFORNIA, Oakland, CA (US)

(21) Appl. No.: 13/549,188

(22) Filed: Jul. 13, 2012

Related U.S. Application Data
(60) Provisional application No. 61/507,182, filed on Jul. 13, 2011.

(51) Int. Cl. H01L 21/208; B05C 3/00; H01L 29/20; C30B 9/12

(52) U.S. Cl. 257/615; 118/50; 438/478; 257/E21.117; 257/E29.089

(57) ABSTRACT

A method of producing a Group-III nitride crystal by coating at least one surface of the seed with a thin wetting layer or film comprised of one or more Group-III and alkali metals.

### CROSS REFERENCE TO RELATED APPLICATIONS

This application claims the benefit under 35 U.S.C. Section 119(e) of co-pending and commonly-assigned applications:

U.S. Provisional Application Ser. No. 61/507,182, filed on Jul. 13, 2011, by Siddha Pimputkar and James S. Speck, entitled “GROWTH OF BULK GROUP-III NITRIDE CRYSTALS AFTER COATING THEM WITH A GROUP-III METAL AND AN ALKALI METAL,” attorneys' docket number 30794.420-US-P1 (2012-021-1);

which application is incorporated by reference herein.

This application is related to the following co-pending and commonly-assigned U.S. patent applications:

U.S. Utility patent application Ser. No. 13/128,092, filed on May 6, 2011, by Siddha Pimputkar, Derrick S. Kamber, James S. Speck, and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys docket number 30794.300-US-WO (2009-288-2), which application is a national stage application that claims the benefit of or priority to P.C.T. International Patent Application Serial No. PCT/US09/063233, filed on Nov. 4, 2009, by Siddha Pimputkar, Derrick S. Kamber, James S. Speck, and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys docket number 30794.300-WO-U1 (2009-288-2), which application claims the benefit under 35 U.S.C. Section 119(e) of U.S. Provisional Patent Application Ser. No. 61/112,550, filed on Nov. 7, 2008, by Siddha Pimputkar, Derrick S. Kamber, James S. Speck, and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys docket number 30794.300-US-P1 (2009-288-1);

U.S. Utility patent application Ser. No. 13/048,179, filed on Mar. 15, 2011, by Siddha Pimputkar, James S. Speck, and Shuji Nakamura, and entitled “GROUP-III NITRIDE CRYSTAL AMMONOTHERMALLY GROWN USING AN INITIALLY OFF-ORIENTED NONPOLAR OR SEMIPOLAR GROWTH SURFACE OF A GROUP-III NITRIDE SEED CRYSTAL,” attorney's docket number 30794.376-US-U1 (2010-585-1), which application claims the benefit under 35 U.S.C. Section 119(e) of U.S. Provisional Patent Application Ser. No. 61/314,095, filed on Mar. 15, 2010, by Siddha Pimputkar, James S. Speck, and Shuji Nakamura, and entitled “GROUP-III NITRIDE CRYSTAL GROWN USING AN INITIALLY OFF-ORIENTED NONPOLAR AND/OR SEMIPOLAR GROUP-III NITRIDE AS A SEED CRYSTAL USING THE AMMONOTHERMAL METHOD AND METHOD OF PRODUCING THE SAME,” attorney's docket number 30794.376-US-P1 (2010-585-1); and

P.C.T. International Patent Application Serial No. PCT/US12/xxxxxx, filed on Jul. 13, 2012, by Siddha Pimputkar, Shuji Nakamura and James S. Speck, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL,” attorneys' docket number 30794.419-WO-U1 (2012-020-2), which application claims the benefit under 35 U.S.C. Section 119(e) of U.S. Provisional Application Ser. No. 61/507,170, filed on Jul. 13, 2011, by Siddha Pimputkar and Shuji Nakamura, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL,” attorneys' docket number 30794.419-US-P1 (2012-020-1), and U.S. Provisional Application Ser. No. 61/507,187, filed on Jul. 13, 2011, by Siddha Pimputkar and James S. Speck, entitled “METHOD OF GROWING A BULK GROUP-III NITRIDE CRYSTAL USING A FLUX BASED METHOD THROUGH PREPARING THE FLUX PRIOR TO BRINGING IT IN CONTACT WITH THE GROWING CRYSTAL,” attorneys' docket number 30794.421-US-P1 (2012-022);

P.C.T. International Patent Application Serial No. PCT/US12/xxxxxx, filed on Jul. 13, 2012, by Siddha Pimputkar, Shuji Nakamura and James S. Speck, entitled “METHOD FOR IMPROVING THE TRANSPARENCY AND QUALITY OF GROUP-III NITRIDE CRYSTALS AMMONOTHERMALLY GROWN IN A HIGH PURITY GROWTH ENVIRONMENT,” attorneys' docket number 30794.422-WO-U1 (2012-023-2), which application claims the benefit under 35 U.S.C. Section 119(e) of U.S. Provisional Application Ser. No. 61/507,212, filed on Jul. 13, 2011, by Siddha Pimputkar and Shuji Nakamura, entitled “HIGHER PURITY GROWTH ENVIRONMENT FOR THE AMMONOTHERMAL GROWTH OF GROUP-III NITRIDES,” attorneys' docket number 30794.422-US-P1 (2012-023-1); U.S. Provisional Application Ser. No. 61/551,835, filed on Oct. 26, 2011, by Siddha Pimputkar, Shuji Nakamura, and James S. Speck, entitled “USE OF BORON TO IMPROVE THE TRANSPARENCY OF AMMONOTHERMALLY GROWN GROUP-III NITRIDE CRYSTALS,” attorneys' docket number 30794.438-US-P1 (2012-248-1); and U.S. Provisional Application Ser. No. 61/552,276, filed on Oct. 27, 2011, by Siddha Pimputkar, Shuji Nakamura, and James S. Speck, entitled “USE OF SEMIPOLAR SEED CRYSTAL GROWTH SURFACE TO IMPROVE THE QUALITY OF AN AMMONOTHERMALLY GROWN GROUP-III NITRIDE CRYSTAL,” attorneys' docket number 30794.439-US-P1 (2012-249-1);

all of which applications are incorporated by reference herein.

### BACKGROUND OF THE INVENTION

1. Field of the Invention

This invention relates to a method of growing a bulk Group-III nitride crystal using a flux method, wherein the Group-III nitride seed crystals are coated with a Group-III metal and an alkali metal.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Bulk Group-III nitride crystals, such as bulk Gallium Nitride (GaN) crystals, are essential for the generation of low defect Group-III nitride substrates, which, in turn, are used for the fabrication of electronic and optoelectronic devices. Bulk Group-III nitride crystals can be grown using various methods, such as an ammonothermal method, a high pressure nitrogen solution growth method, or other flux methods, such as a sodium flux method, wherein a major component of the flux is elemental sodium (Na).

Of all the methods currently used to produce bulk Group-III nitride crystals, the sodium flux method appears the most promising due to its demonstrated growth rates and resulting properties of the crystals. Specifically, the sodium flux method, which grows bulk GaN crystals from a flux that contains at least a Group-III element (such as Ga), an alkali metal (such as Na), and some dissolved nitrogen, has demonstrated high growth rates, e.g., approximately 30 micrometers per hour for sodium flux growth as compared to approximately 5 micrometers per hour for ammonothermal growth.

What is needed in the art, then, is a method that provides further improvements to the sodium flux method for the growth of bulk Group-III nitride crystals. The present invention satisfies this need.

### SUMMARY OF THE INVENTION

To overcome the limitations in the prior art described above, and to overcome other limitations that will become apparent upon reading and understanding the present specification, the present invention discloses a method of growing bulk Group-III nitride crystals using flux methods. The flux may contain Group-III and alkali metals, such as Ga and Na, and other additives to modify the solubility of nitrogen into the flux, which is needed for the growth of Group-III nitride crystals. In order to further enhance growth rates, and additionally modify the properties of a growing Group-III nitride crystal, it is beneficial to reduce the distance needed for nitrogen to migrate from its source (the atmosphere) to the crystal's surface. This invention proposes coating at least one surface of a Group-III nitride crystal with a thin wetting layer or film of flux-containing material comprised of the Group-III and alkali metals, before and during the sodium flux growth, thereby reducing the overall diffusion length of nitrogen and increasing the growth rate of the crystal.

### BRIEF DESCRIPTION OF THE DRAWINGS

Referring now to the drawings in which like reference numbers represent corresponding parts throughout:

FIG. 1 is a schematic of an apparatus used in the sodium flux method according to one embodiment of the present invention.

FIG. 2 is a flowchart that illustrates an exemplary process for performing sodium flux growth according to one embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

This invention provide an improved rate of flux growth of Group-III nitride crystals by thinning the layer of material around the growing Group-III nitride crystal, thereby reducing the distance a newly dissolved nitrogen atom, radical or molecule needs to travel until it integrates into the growing crystal. Specifically, the present invention provides an environment with sufficient Group-III metals and alkali metals, such that a thin Group-III-containing and alkali-containing layer adheres to the surface of the Group-III nitride crystal, to form a continuous wetting layer, even if any further supplied Group-III metals and alkali metals then form droplets that no longer provide full, continuous surface coverage. The material used to coat the crystal typically has some nitrogen present, and the crystal and/or the flux is at least partially exposed to a nitrogen-containing environment.

Sodium Flux Growth of Group-III Nitride Crystals

In its most fundamental form, the sodium flux method grows Group-III nitride crystals in a flux comprising a fluid or melt containing at least one Group-III metal, such as Al, Ga and/or In, and at least one alkali metal, such as Na. The fluid is contained within a chamber or vessel, and is subject to conditions that allow for the addition or removal of nitrogen to or from the fluid. For example, the fluid may be placed within a nitrogen-containing atmosphere and heated to a desirable temperature (typically greater than 700° C.), wherein the fluid is brought into contact with one or more surfaces of a seed upon which the Group-III nitride crystal is formed.

The challenges this growth method faces are primarily related to the solubility of nitrogen into the flux and, once the nitrogen has been dissolved into the flux, the diffusion time required for the nitrogen to come into the vicinity of the growing Group-III nitride crystal. Multiple methods have been proposed, such as stirring or agitating the fluid, to increase the amount of dissolved nitrogen in close proximity of the crystal and, although these methods may be effective, they are not necessarily scalable and economic. This invention proposes an alternative method of preparing a crystal for the sodium flux growth by coating it with a continuous thin wetting layer comprised of one or more Group-III metals and one or more alkali metals.

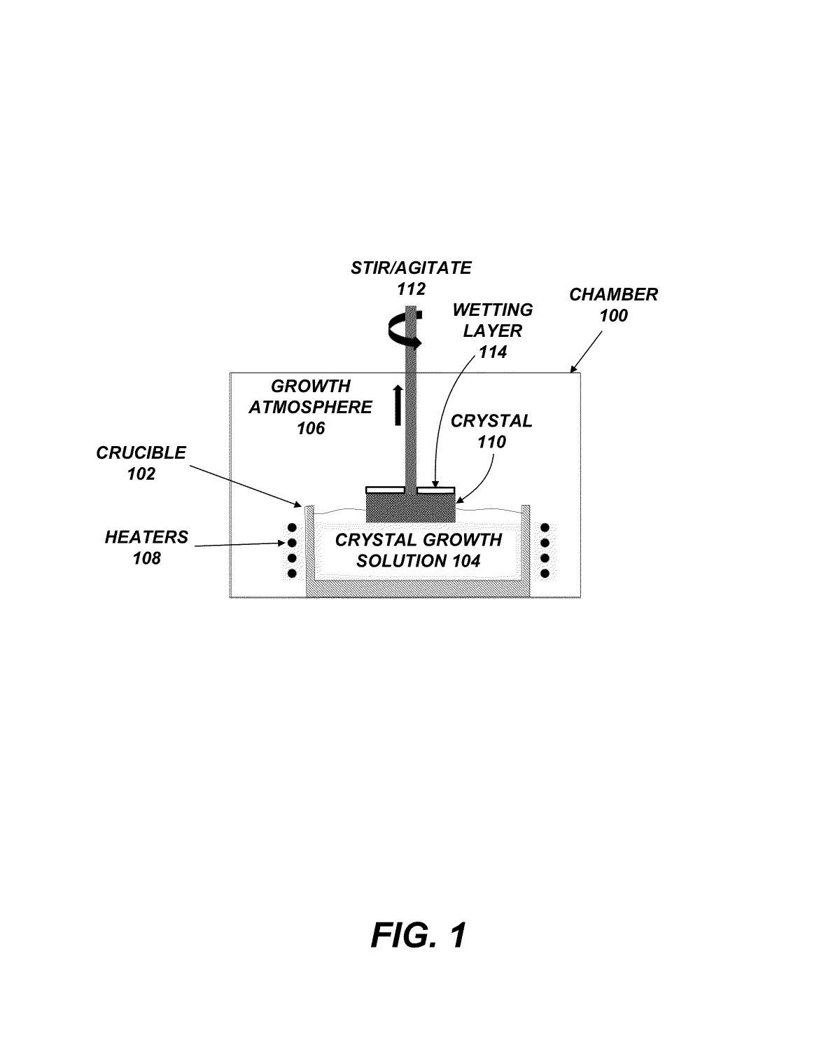

FIG. 1 is a schematic of an apparatus used in the sodium flux method in its most general form. In one embodiment of the present invention, the sodium flux method makes use of a vessel or chamber 100 (which may be open or closed) having a crucible 102 that contains a fluid 104 that is a crystal growth solution comprised of at least one Group-III metal, such as Al, Ga and/or In, and at least one alkali metal, such as Na. The fluid 104 may contain any number of additional elements, compounds, or molecules to modify growth characteristics and crystal properties, such as B, Li, K, Rb, Cs, Be, Mg, Ca, Sr, Ba, Sr, C, Bi, Sb, Sn, Be, Si, Ge, Zn, P and/or N.

Additionally, the chamber 100 contains a growth atmosphere 106 in which the fluid 104 is placed that can be a nitrogen-containing atmosphere 106, including, but not limited to, molecules such as diatomic N₂, ammonia NH₃, hydrazine N₂H₆, and atomic nitrogen N, or an atmosphere 106 with only trace amounts of nitrogen present, for example, an atmosphere 106 comprised mainly of hydrogen, argon, etc. The atmosphere 106 may be at vacuum, or may have a pressure greater than approximately 1 atmosphere (atm) and up to approximately 1000 atm.

The crucible 102 may include one or more heaters 108 so that fluid 104 may be heated and then held at one or more set temperatures, and one or more temperature gradients may be established within the chamber 100. In one embodiment, the fluid 104 is held at a temperature greater than approximately 200° C. and below approximately 1200° C. during growth.

The chemical potential of the fluid 104 may be raised or lowered with respect to vacuum through the use of a power source operating at arbitrary frequencies (f>=0 Hz) and voltages. The fluid 104 and atmosphere 106 in which it has been placed may be subject to electromagnetic fields, both static and/or dynamic.

Once the chamber 100 containing the fluid 104 has been adequately prepared, a seed 110 can then be brought into contact with the fluid 104, wherein the seed 110 and/or the fluid 104 is at least partially exposed to the nitrogen-containing atmosphere 106. Once the seed 110 has been brought into contact with the fluid 104, the seed 110 and/or fluid 104 may be subject to mechanical movements 112, such as stirring or agitating, to enhance the growth of the Group-III nitride crystal.

In a preferred embodiment, the seed 110 itself is a Group-III nitride crystal, such as GaN, and may be a single crystal or a polycrystal. However, this should not be seen as limiting for this invention. This invention specifically includes growing a Group-III nitride crystal on an arbitrary material, wherein the seed 110 may be an amorphous solid, a polymer containing material, a metal, a metal alloy, a semiconductor, a ceramic, a non-crystalline solid, a poly-crystalline material, an electronic device, an optoelectronic device, etc.

When the seed 110 is a Group-III nitride crystal, it may have one or more facets exposed, including facets that are polar, nonpolar and semipolar planes. For example, the Group-III nitride seed crystal 110 may have a large polar c-plane {0001} facet or a {0001} approaching facet exposed; or the Group-III nitride seed crystal 110 may have a large nonpolar m-plane {10-10} facet or a {10-10} approaching facet exposed; or the Group-III nitride seed crystal 110 may have a large semipolar {10-11} facet or a {10-11} approaching facet exposed; or the Group-III nitride seed crystal 110 may have a large nonpolar a-plane {11-20} facet or a {11-20} approaching facet exposed.

In one embodiment of the present invention, the seed 110 is prepared prior to growth by coating the seed 110 with a thin wetting layer 114 comprised of one or more Group-III metals and one or more alkali metals. Moreover, the thin wetting layer 114 is maintained on the Group-III nitride crystal during growth. The thin wetting layer 114 minimizes the distance the nitrogen must travel to integrate to the crystal, namely, through the thin wetting layer 114 rather than the flux 104.

The coating of the seed 110 or the resulting Group-III crystal is based on evaporation from a liquid and/or solid source, containing the Group-III and alkali metals, onto the seed 110 and/or the resulting crystal, which results in the formation of the thin wetting layer 114 onto the surfaces of the seed 110 or the resulting crystal. Consequently, the seed 110 and/or the resulting crystal are continuously or intermittently brought into contact with the flux 104 by dripping or flowing the flux 104 over the surfaces of the seed 110 or resulting crystal, or by submersing or submerging the seed 110 or resulting crystal into the flux 104 itself. Preferably, this occurs with at least one facet of the seed 110 or resulting crystal and/or the flux 104 exposed to the atmosphere 106 or at least close to the interface between the flux 104 and the atmosphere 106.

Nitrogen is then deposited onto the wetting layer 114, or conditions are provided such that nitrogen goes onto the wetting layer 114, wherein the nitrogen from the wetting layer 114, incorporates into the seed 110 and/or resulting crystal. For example, the wetting layer 114 may be bombarded with nitrogen (e.g., nitrogen gas at high pressure), and once there is enough nitrogen, nitrogen incorporates into the seed 100 and/or resulting crystal. For example, the Ga is a source for growth of Group III element on the seed 110 and/or crystal, the Na is a catalyst for the growth and, as the nitrogen goes into the alloy, it chemically reacts with the Ga.

The resulting Group-III nitride crystal that is grown on the seed 110 is characterized as AlₓB_{y}Ga_{z}In_{(1-x-y-z})N, where 0<=x<=1, 0<=y<=1, 0<=z<=1, and x+y+z<=1. For example, the Group-III nitride crystal may be, but is not limited to, AlN, GaN, InN, AlGaN, AlInN, InGaN, etc. The Group-III nitride crystal may also have layers with different compositions, and the Group-III nitride crystal may have layers with different structural, electronic, optical, and/or magnetic properties.

Process Flowchart

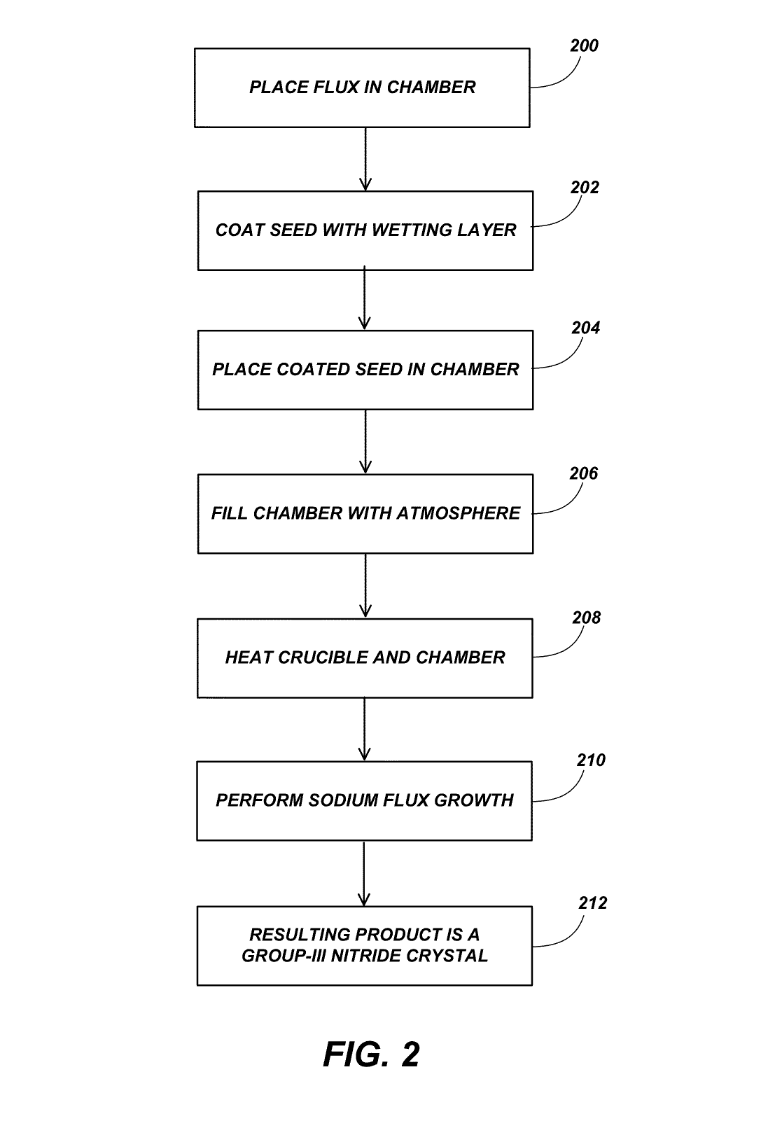

FIG. 2 is a flowchart that illustrates an exemplary process for performing the method of sodium flux growth according to one embodiment of the present invention.

Block 200 represents placing a flux comprised of a fluid or melt 104 into a crucible 102 of a vessel or chamber 100, wherein the fluid 104 is a crystal growth solution comprised of at least one Group-III metal, such as Al, Ga and/or In, and at least one alkali metal, such as Na.

Block 202 represents coating the seed 110 prior to growth with a thin wetting layer 114 comprised of the flux.

Block 204 represents placing the coated seed 119 into the chamber 100.

Block 206 represents filling the chamber 100 with a growth atmosphere 106 to a desired pressure level, wherein the growth atmosphere 106 can be a nitrogen-containing atmosphere 106 or an atmosphere 106 with only trace amounts of nitrogen present.

Block 208 represents heating the crucible 102 and/or chamber 100 to one or more set temperatures, and establishing one or more temperature gradients within the chamber 100.

Block 210 represents, once the chamber 100 containing the fluid 104 has been adequately prepared and the seed 110 coated with the thin wetting layer 114, growing the Group-III nitride crystal by bringing the seed 110 into contact with the fluid 104 or by bringing the fluid 104 into contact with the seed 110, wherein the seed 110 and/or the fluid 104 is at least partially exposed to the nitrogen-containing atmosphere 106. This Block may include subjecting the seed 110 and/or fluid 104 to mechanical movements 112, such as stirring or agitating or spray coating, to maintain the thin wetting layer 114 on the seed 110 and the growing Group-III crystal, in order to reduce the distance the nitrogen in the atmosphere 106 needs to travel to integrate into the seed 110, i.e., the nitrogen need only pass through the thin wetting layer 114 rather than through the flux 104 contained within the crucible 102.

Block 212 represents the resulting product created by the process, namely, a Group-III nitride crystal grown by the method described above. A Group-III nitride substrate may be created from the Group-III nitride crystal, and a device may be created using the Group-III nitride substrate.

Seed Crystal Coating Layer

As noted above, the coating applied to the seed crystal in the present invention, prior to and/or during the growth of the Group-III nitride crystals using the sodium flux method, improves the growth rate by reducing the distance a newly dissolved nitrogen atom, radical or molecule needs to travel until it integrates into the growing crystal. This is accomplished by maintaining a thin wetting layer of material around the growing Group-III nitride crystal prior to and/or during the sodium flux growth.

It has been seen in other growth techniques, such as MBE (Molecular Beam Epitaxy), that in an environment with sufficient Ga, a few monolayers of Ga adhere to the surface and form a continuous wetting layer. Using the MBE technique, any further supplied Ga then form droplets, which no longer provide full, continuous surface coverage. The present invention also uses the concept of a wetting layer, but in conjunction with the sodium flux method, wherein the wetting layer has a thickness of one or more monolayers of the Group-III metals and the alkali metals, that coats the Group-III nitride seed crystal prior to and during the sodium flux growth.

The method used to provide and maintain the wetting layer is not limited. In one embodiment, the wetting layer is not thicker than approximately 5-10 monolayers of the Group-III nitride crystal, although in another embodiment, the wetting layer is not thicker than approximately 1-5 mm of the Group-III nitride crystal. Moreover, while it is beneficial to only have a few monolayers of Group-III and alkali metal material around the crystal, it is further disclosed that a few micrometers of Group-III and alkali metal material around the crystal may be beneficial for overall growth characteristics.

The method used for coating the crystal may be comprised from the following non-exclusive list:

1. Physically dipping the crystal into solution and then removing it, while subjecting the crystal to a nitrogen-containing environment for extended periods of time.

2. Coating the crystal by placing it in proximity of one or more crucibles containing one or more Group-III elements and alkali metals that are melted, wherein a stream of one or more Group-III elements and/or alkali metals are directed towards the crystal.

3. Moving the melt containing one or more Group-III elements and alkali metals, so that it is brought into contact with the crystal. This could be done by dripping the melt onto the crystal from above and letting it coat the crystal while gravity pulls the melt over the surfaces of the crystal.

The method of the present invention may provide Group-III nitride substrates, which, in turn, can be used for the generation or fabrication of electronic and optoelectronic devices.

Possible Modifications and Improvements

Further modifications and improvements to this invention can be envisioned as the following:

1. The viscosity of the fluid may be modified by changing its temperature, pressure, and/or adding other elements, compounds, or materials, before and/or during growth.

2. The vapor pressure of the various elements of interest can be modified by changing their temperature, pressure, and/or adding other elements, compounds, or materials, before and/or during growth.

3. The melt that coats the crystal may have any number of additional elements, molecules, and compounds present, which may further modify the:
a. growth rate of the crystal;
b. electronic properties of the crystal;
c. optical properties of the crystal;
d. magnetic properties of the crystal;
e. structural properties of the crystal;
f. surface roughness during growth;
g. predominate or predominant planes present during growth;
h. size, density and distribution of growth fronts, growth planes, microfacets, macrofacets;
i. impurity uptake into the crystal.

4. The orientations of exposed surfaces of the Group-III nitride crystal can be any combination of polar, non-polar and/or semi-polar orientations.

5. The use of specially prepared crystal with a specific surface structure and/or orientations to enforce a particular growth mode and/or direction during growth.

6. The control of layer thickness on the crystal may be achieved through modifications in the viscosity of the melt, the deposition rate of arriving material, the speed at which the crystal is moved, the speed at which the crystal is rotated, etc.

7. The orientation of the crystal may be positioned such that its main (i.e., largest) surface is fully exposed (e.g., parallel), at an angle to, or perpendicular to, the melt or a stream of elements that, at least in part, make up the melt.

8. The environment in which the crystal is placed, after having at least a monolayer coating of Group-III nitride material and alkali metal applied, may include at least one nitrogen-containing material, but may also specifically not contain nitrogen. Materials that may be useful for the successful growth include atomic nitrogen (N), diatomic nitrogen (N2), ammonia (NH3), hydrazine (N2H4), nitrogen plasma, nitrogen radicals, and nitrogen plasma.

9. The composition of the flux may be modified and changed at any time during growth.

Advantages and Improvements

The present invention may provide a method to create cheap, high quality Group-III nitride substrates.

Nomenclature

The terms “Group-III nitride” or “III-nitride” or “nitride” as used herein refer to any composition or material related to (B, Al, Ga, In)N semiconductors having the formula B_{w}AlₓGa_{y}In_{z}N where 0≦w≦1, 0≦x≦1, 0≦y≦1, 0≦z≦1, and w+x+y+z=1. These terms as used herein are intended to be broadly construed to include respective nitrides of the single species, B, Al, Ga, and In, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (B, Al, Ga, In)N component species are present, all possible compositions, including stoichiometric proportions as well as off-stoichiometric proportions (with respect to the relative mole fractions present of each of the (B, Al, Ga, In)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of Group-III nitrides. When identifying crystal orientations, directions, terminations and polarities using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

Many Group-III nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in Group-III nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero l Miller index. Subsequent semipolar layers are equivalent to one another, so the crystal will have reduced polarization along the growth direction.

### REFERENCES

The following references are incorporated by reference herein.

[1] Takakura, N. et al., Semiconductor Light Emitting Element Employing Group-III Metal Nitride Crystal and Process for Producing Group-III Metal Nitride Crystal. Japanese Patent Publication No. JP2005175276A2, published on Jun. 30, 2005.

[2] Sasaki, T., Mori, Y., Yoshimura, M., Kawamura, F. and Hirota, R., Method of Manufacturing Group-III Nitride Crystal. U.S. Pat. No. 7,288,151, issued Oct. 30, 2007.

[3] Sasaki, T. et al., Method for Manufacturing Nitride Single Crystal of Group-III Element, Apparatus Used for the Same, and Nitride Single Crystal of Group-III Element Obtained by the Method. Japanese Patent Publication No. JP2006089376A2, published on Apr. 6, 2006.

[4] Sasaki, T., Mori, Y., Yoshimura, M., Kawamura, S. and Hirota, T., Production Method for Group-III Nitride Crystal. Japanese Patent Publication No. JP2005194147A2, published on Jul. 21, 2005.

[5] Takakura, N. et al., Semiconductor Light Emitting Element Employing Group-III Metal Nitride Crystal and Process for Producing Group-III Metal Nitride Crystal. Japanese Patent Publication No. JP2005175275A2, published on Jun. 30, 2005.

[6] Sasaki T. et al., Method For Manufacturing Nitride Single Crystal Of Group III Element, Apparatus Used For The Same, And Nitride Single Crystal Of Group III Element Obtained By The Method, Japanese Patent Publication No. JP2004307333A2, published on Nov. 4, 2004.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of growing a Group-III nitride crystal using a flux comprised of one or more Group-III metals and one or more alkali metals, comprising:
coating at least one surface of a seed with a thin wetting layer comprised of one or more Group-III metals and one or more alkali metals; and
growing the Group-III nitride crystal on the seed in a growth atmosphere, by bringing the flux into contact with the seed or by bringing the seed into contact with the flux, wherein the seed or flux is at least partially exposed to the growth atmosphere.

2. The method of claim 1, wherein the seed is a Group-III nitride crystal.

3. The method of claim 1, wherein the Group-III metal is one or more of Al, Ga or In, and the alkali metal is Na.

4. The method of claim 1, wherein the coating step is performed intermittently or continuously.

5. The method of claim 1, wherein the coating step is performed by dripping or flowing the flux over one or more surfaces of the seed.

6. The method of claim 1, wherein the coating step is performed by submersing or submerging the seed within the flux and placing one facet of the seed within some specified distance of an interface between the flux and the atmosphere.

7. The method of claim 1, further comprising subjecting the seed, the Group-III nitride crystal, or the flux to mechanical movements, such as stirring or agitating, to shorten a distance required for the nitrogen to integrate with the seed or the Group-III nitride crystal.

8. The method of claim 1, wherein the growing step further comprises maintaining the thin wetting layer on the Group-III nitride crystal during the growth of the Group-III nitride crystal.

9. The method of claim 1, wherein the Group-III nitride crystal has one or more polar, non-polar or semi-polar facets exposed.

10. A Group-III nitride crystal grown using the method of claim 1.

11. An apparatus for growing a Group-III nitride crystal using a flux comprised of one or more Group-III metals and one or more alkali metals, comprising:
means for coating at least one surface of a seed with a thin wetting layer comprised of one or more Group-III metals and one or more alkali metals; and
a chamber for growing the Group-III nitride crystal on the seed in a growth atmosphere, by bringing the flux into contact with the seed or by bringing the seed into contact with the flux, wherein the seed or flux is at least partially exposed to the growth atmosphere.

12. The apparatus of claim 11, wherein the seed is a Group-III nitride crystal.

13. The apparatus of claim 11, wherein the Group-III metal is one or more of Al, Ga or In, and the alkali metal is Na.

14. The apparatus of claim 11, wherein the means for coating is performed intermittently or continuously.

15. The apparatus of claim 11, wherein the means for coating is performed by dripping or flowing the flux over one or more surfaces of the seed.

16. The apparatus of claim 11, wherein the means for coating is performed by submersing or submerging the seed within the flux and placing one facet of the seed within some specified distance of an interface between the flux and the atmosphere.

17. The apparatus of claim 11, further comprising means for subjecting the seed, the Group-III nitride crystal, or the flux to mechanical movements, such as stirring or agitating, to shorten a distance required for the nitrogen to integrate with the seed or the Group-III nitride crystal.

18. The apparatus of claim 11, wherein the chamber further comprises means for maintaining the thin wetting layer on the Group-III nitride crystal during the growth of the Group-III nitride crystal.

19. The apparatus of claim 11, wherein the Group-III nitride crystal has one or more polar, non-polar or semi-polar facets exposed.
